(19) United States
(12) Patent Application Publication
(10) Pub. No.: US 2012/0167817 A1
(43) Pub. Date: Jul. 5, 2012

(54) METHOD AND DEVICE FOR PRODUCING SILICON BLOCKS

(76) Inventors: Bernhard FREUDENBERG, Coburg (DE); Marc DIETRICH, Grobschirma (DE); Mark HOLLATZ, Dresden (DE); Melanie HENTSCHE, Dresden (DE); Doreen NAUERT, Grobschirma (DE); Markus APEL, Aachen (DE)

(21) Appl. No.: 12/981,632

(22) Filed: Dec. 30, 2010

(51) Int. Cl. C30B 19/06

(52) U.S. Cl. 117/54; 117/206

(57) ABSTRACT

A method for producing silicon blocks comprises providing a crucible for receiving a silicon melt, with a base and a plurality of side walls connected to the base, attaching nuclei at least on an inner side of the base of the crucible, the nuclei having a melt temperature, which is greater than the melt temperature of silicon, filling the crucible with the silicon melt, solidifying the silicon melt beginning on the nuclei and removing the solidified silicon from the crucible.

### FIELD OF THE INVENTION

The invention relates to a method and a device for producing silicon blocks.

### BACKGROUND OF THE INVENTION

The production of large-volume semiconductor bodies, in particular silicon blocks, is of fundamental significance for producing silicon cells. Apart from the production costs, the property profile of the silicon block is primarily established during production and is decisive for the achievable efficiency of the silicon cells. The production of silicon blocks is based on the solidification of a silicon melt, it being possible to control the crystallisation growth by means of so-called nucleating agents.

Methods are known from DE 196 07 098 C2 and WO 2007/084934 A2, which use planar silicon nuclei to solidify the silicon melt. It is disadvantageous that the temperature on an inner side of a crucible base has to be within a very narrow interval for methods of this type. Because of the restricted process stability following from this, these methods are only conditionally suitable for the mass production of silicon blocks.

Methods are known from DE 10 2005 032 790 A1, DE 10 2005 032 789 A1 and DE 10 2005 028 435 A1, according to which the inner side of a crucible is coated to avoid silicon adhering to the crucible. Further coatings are known, for example, from DE 699 12 668 T2 and JP 2005-022949 AA. The coatings are used to avoid the silicon adhering to the crucible container, but at the same time bring about a reduced nuclei activity, which counteracts a nucleation.

WO 2007/123169 A1 describes the use of nuclei in a gas compartment, contact between the silicon melt and the nuclei requiring a strong undercooling of the melt in the gas flow. US 2007/007974 A1 concerns a nucleating agent, which is dissolved in the silicon melt and acts as a nucleus centre there. These methods are complex with regard to the management of the process and therefore expensive.

### SUMMARY OF THE INVENTION

The invention is based on the object of providing a method and a device for producing silicon, so the resulting particle size of the silicon can be reproduced and adjusted in a defined manner in a simple method.

The object is achieved by a method for producing silicon blocks comprising the method steps of providing a crucible for receiving a silicon melt, with a base and a plurality of side walls connected to the base, attaching nuclei at least to an inner side of the base of the crucible, wherein the nuclei have a melt temperature, which is greater than the melt temperature of silicon, filling the crucible with silicon melt, solidifying the silicon melt beginning on the nuclei and removing the solidified silicon from the crucible. The object is further achieved by a crucible for producing silicon with a base, a plurality of side walls and nuclei on at least an inner side of the base of the crucible, wherein the base and the side walls partially surround an interior to receive a silicon melt and wherein the nuclei have a melt temperature, which is greater than the melt temperature of silicon. The core of the invention is that nuclei are provided on at least an inner side of a crucible base and allow planar nucleation. For this purpose, the nuclei are made of a material which is different from silicon, the melt temperature of the nuclei being greater than the melt temperature of silicon. The nuclei bring about a reduction in the nucleation energy for the crystallisation of the silicon compared to necessary nucleation energy in the remaining regions of the crucible, which is in contact with the silicon melt. The nuclei are also called nucleating agents. The silicon nuclei on the nucleating agents thus initially grow primarily laterally along the crucible base before the bulk nucleation having a preferred direction oriented perpendicular to the crucible base starts. It is consequently possible to control and to reduce the number of crystal nuclei. It is also possible to arrange the nuclei on side walls of the crucible. Moreover, the base and/or the side walls may have a coating. In each case, the nuclei are arranged on the inner side of the crucible in such a way that they come into direct contact with the silicon melt.

Additional features and details of the invention emerge from the following description of four embodiments with the aid of the drawings.

### BRIEF DESCRIPTION OF THE DRAWINGS

FIG. 1 shows a longitudinal section of a crucible according to the invention in accordance with a first embodiment with nuclei anchored in the crucible base,

FIG. 2 shows a view of a crucible according to FIG. 1 in accordance with a second embodiment with nuclei arranged directly on the crucible base,

FIG. 3 shows a view of a crucible corresponding to FIG. 1 in accordance with a third embodiment with nuclei in a coating of the crucible, and

FIG. 4 shows a view of a crucible corresponding to FIG. 1 in accordance with a fourth embodiment with nuclei arranged on the coating.

### DESCRIPTION OF THE PREFERRED EMBODIMENTS

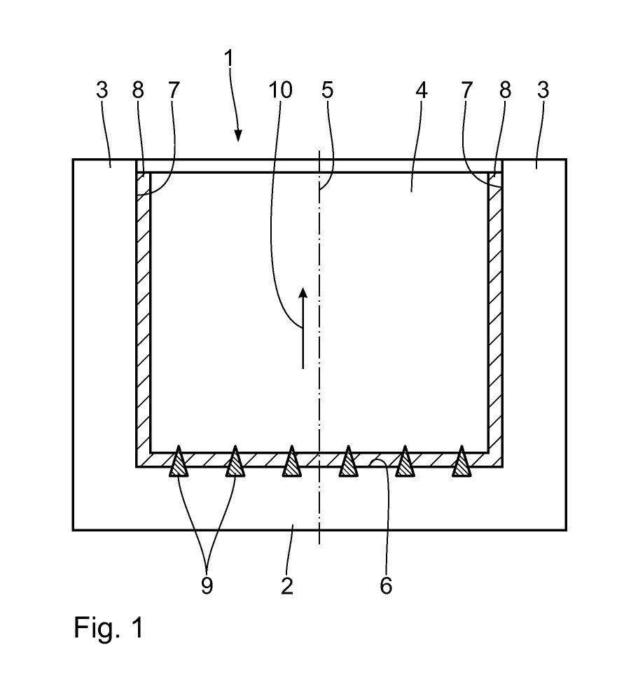

A crucible 1 shown in FIG. 1 has a base 2 and a plurality of side walls 3 rigidly connected to the base 2. The base 2 and the side walls 3 partially surround an interior 4 to receive a silicon melt. The crucible 1 has a longitudinal axis 5 oriented perpendicular to the base 2. A coating 8 is provided on an inner side 6 of the base 2 and on inner sides 7 of the side walls 3. It is also possible for the crucible 1 to be uncoated. A plurality of nuclei 9 are anchored in the base 2, the nuclei 9 being arranged distributed in a structured manner in the base 2. In this case, the nuclei 9 are provided in such a way that they project through the coating 8 into the interior 4 of the crucible 1 and come into contact with the silicon melt to be poured into the crucible 1. It is also possible for the nuclei 9 to be anchored in accordance with a statistical distribution and therefore without a specific preferred orientation in the crucible 1. In particular, it is also possible to provide the nuclei 9 in at least one side wall 3.

The nuclei 9 have at least one compound from a group of elements from the III, IV or V main group of the Periodic Table of elements. In particular, compounds of elements of the III, IV or V main group with oxygen are also possible, Al₂O₃ being above all particularly suitable. BeO has also proven to be a suitable nucleating agent for the crucible 1 according to the invention even if Be is an element of the II main group.

Moreover, ceramic materials have a small lattice disregistry with respect to silicon and are well wetted by the silicon melt as they have a chemical affinity to silicon, such as, for example SiC. Moreover, further carbides, but also nitrides, phosphides and oxides and therefore also silicates are possible as alternative nuclei 9.

Compounds of elements of the III and V main group have proven to be particularly suitable as these elements are also used as doping materials and therefore their effect as extraneous materials is reduced. Further possible materials for the nuclei 9 are therefore SiO, SiO₂, Si₃N₄, BN, BP, AlP, AlAs and AN. These compounds have in common that their melt temperature is above that of silicon and is therefore greater than 1412° C.

The effective nuclei density for the method according to the invention to produce silicon is particularly important, which will be dealt with in more detail below. The effective nuclei density in the crucible 1 according to the invention is between 0.001 and 100 nuclei per cm², in particular between 0.01 and 10 nuclei per cm² and, in particular, between 0.03 and 5 nuclei cm². In this case, the nuclei 9 used have a size of 0.01 to 50000 μm, in particular between 0.1 and 5000 μm and, in particular, between 1 and 500 μm.

The method according to the invention for producing silicon with the crucible 1 according to the invention will be described in more detail below. Firstly, the crucible 1 with the base 2 and the side walls 3 is provided. Nuclei 9 are then provided at least on the inner side 6 of the base 2 in such a way that they are rigidly anchored to the base 2 and can come into direct contact with the silicon melt, even when the base 2 and/or the side walls 3 have a coating 8. This crucible 1 is filled with the silicon melt, the silicon melt, proceeding from the nuclei 9, firstly solidifying primarily in a planar manner until the inner side 6 provided with the nuclei 9 is substantially covered with planar silicon particles. A bulk crystal growth then takes place in a preferred growth direction 10 oriented perpendicular to the inner sides 6, 7. Finally, the silicon body which has solidified in the crucible 1 is removed.

The nucleation on the nuclei 9 will be described in more detail below. Owing to the use of the nuclei, a critical undercooling necessary for nucleation compared to the remaining regions of the inner sides 6, 7 of the crucible, which have no nuclei 9, is reduced. The use of nuclei 9 means that the nucleation starts at a temperature reduction of a few K in relation to the melt temperature of silicon, whereas a nucleation at a greater temperature difference from the silicon melt temperature is to be expected at the remaining points of the inner sides 6, 7 of the crucible. The nuclei 9 growing first determine the structure of the semiconductor body.

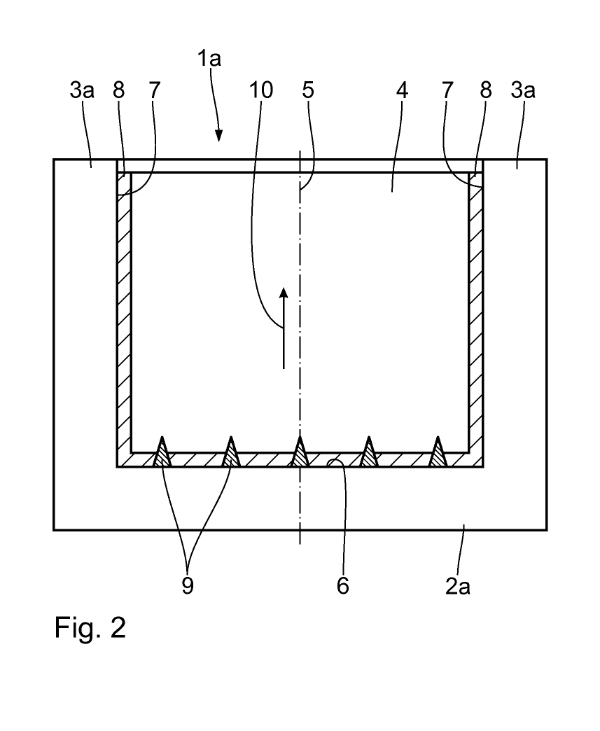

A second embodiment of the invention will be described below with reference to FIG. 2. Structurally identical parts have the same reference numerals as in the first embodiment, reference being hereby made to the description thereof. Structurally different, but functionally similar parts have the same reference numerals with an a placed afterwards. An important difference of the crucible 1a is the arrangement of the nuclei 9, which are provided directly on the base 2a of the crucible 1a. In this case, the nuclei 9 can also be arranged randomly distributed as in the first embodiment of the crucible according to the invention and also be arranged on the inner sides 7 of the side walls 3a. Accordingly, it is also possible to configure the crucible 1a without a coating 8.

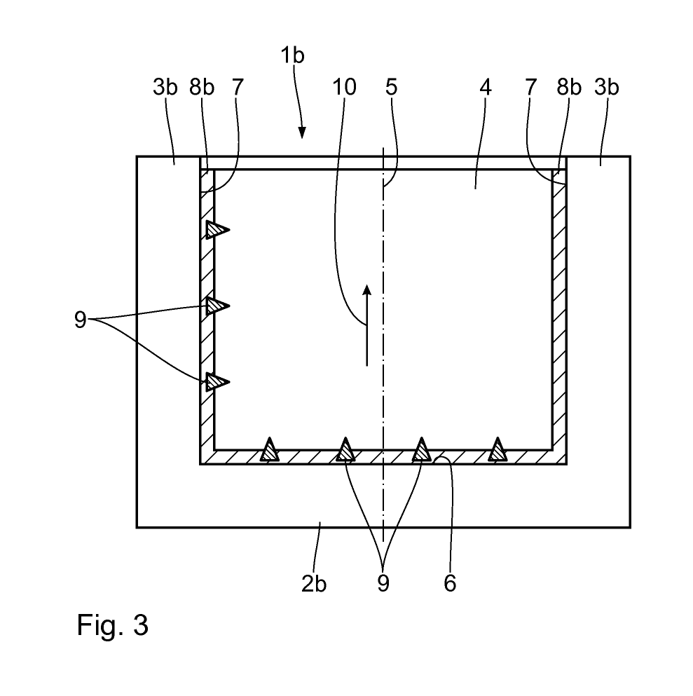

A third embodiment of the invention will be described below with reference to FIG. 3. Structurally identical parts have the same reference numerals as in the first embodiment, reference being hereby made to the description thereof. Structurally different, but functionally similar parts have the same reference numerals with a b placed afterwards. The important difference from the first embodiment is the arrangement of the nuclei 9 in the coating 8b of the crucible 1b. This means that the nuclei 9 are independent of the base 2b and the side walls 3b of the crucible 1b. In particular, neither the base 2b nor the side walls 3b have nuclei 9 and are also not connected to the nuclei 9. The nuclei 9 are arranged in the coating 8b in accordance with the first embodiment in such a way that they project at least partially into the interior 4 of the crucible 1b for nucleation. In the third embodiment, the coating 8b of the crucible 1b is imperative. Thus, the nucleation proceeding from the nuclei 9 starts directly on the coating 8b. As also in the two first embodiments, the nuclei 9 may be arranged statistically distributed in the coating 8b. In particular, it is possible for only certain walls of the crucible 1b to be provided with nuclei, while other walls are free of nuclei. In the embodiment shown, the inner side 6 of the base 2b and the inner side 7 of the side wall 3b shown on the left in FIG. 3 has nuclei 9.

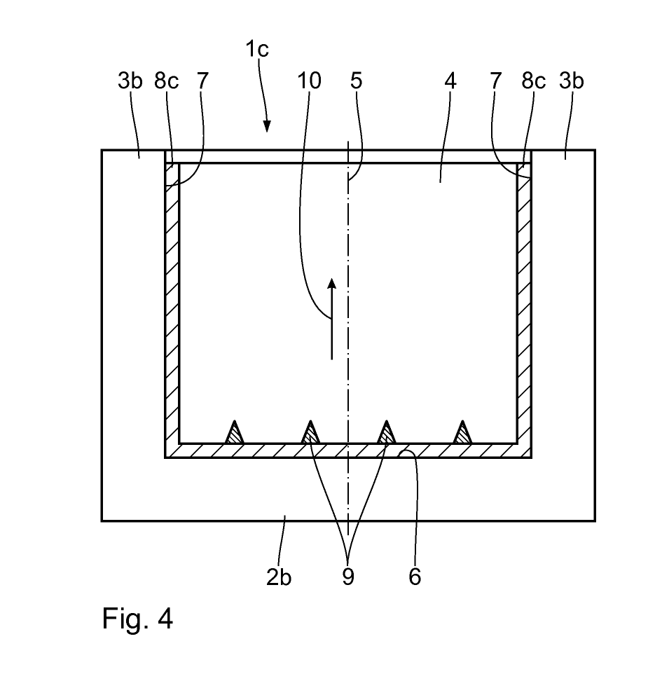

A fourth embodiment of the invention will be described below with reference to FIG. 4. Structurally identical parts have the same reference numerals as in the first embodiment, reference being hereby made to the description thereof. Structurally different, but functionally similar parts have the same reference numerals with a c placed afterwards. The important difference from the first embodiment is the arrangement of the nuclei 9 on the coating 8, it being possible for the nuclei 9 to be loosely applied or burnt into the coating 8 of the crucible 1d. The nuclei 9 project into the interior 4 of the crucible 1d and, as an alternative to the arrangement shown distributed in a structured manner, may also be arranged statistically distributed. It is also possible for the side walls 3 of the crucible 1c to have nuclei 9.

According to a further embodiment not shown in a figure, monocrystalline nuclei 9 are used on the crucible base 2, which have a preferred growth direction 10, which is oriented parallel to the longitudinal axis 5. For this purpose, SiC scales are preferably used, which, because of their planar geometry embed on or in the coating 8 of the crucible 1 and therefore have the preferred growth direction 10 along the growth direction of the silicon melt. Accordingly, the preferred growth direction 10 also applies to the solidifying silicon, which has a particularly positive effect on subsequent processes during the production of silicon cells. This applies, in particular, to a surface texture of a silicon cell.

A preferred possibility for producing the nucleating particles on the inner sides 2, 3 of the crucible 1 or on its coating 8, is the use of a carrier medium in the form of a paste or a liquid with dispersed nuclei, in the form of a paste with dispersed metal, such as, for example, aluminium paste with rear metalisation, or in the form of precursors. In this case, the paste or the precursor is applied with the aid of a spray device, such as, for example, according to the principle of an inkjet print by spraying on, in accordance with a “gateau cream spray bag” by dropping on or by punch pressure on the inner sides 2, 3. By means of a following temperature process step, the starting materials of the paste with dispersed metal or of the precursor react to form the nucleating material and the particles of the paste with dispersed nuclei sinter with the crucible surface or its coating 8. The carrier medium evaporates before the silicon melts.

What is claimed is:

1. A method for producing silicon blocks comprising the method steps
a. providing a crucible (1; 1a; 1b; 1c) for receiving a silicon melt, with
i. a base (2; 2a; 2b) and
ii. a plurality of side walls (3; 3a; 3b) connected to the base (2; 2a; 2b),
b. attaching nuclei (9) at least to an inner side (6) of the base (2; 2a; 2b) of the crucible (1; 1a; 1b; 1c),
i. wherein the nuclei (9) have a melt temperature, which is greater than the melt temperature of silicon,
c. filling the crucible (1; 1a; 1b; 1c) with silicon melt,
d. solidifying the silicon melt beginning on the nuclei (9) and
e. removing the solidified silicon from the crucible (1; 1a; 1b; 1c).

2. A method according to claim 1, wherein the nuclei (9) have at least one compound from a group of elements of the IIIrd, IVth or Vth main group.

3. A method according to claim 1, wherein the nuclei (9) have at least a compound of elements of the IIIrd and Vth main group.

4. A method according to claim 2, wherein the compounds have oxygen.

5. A method according to claim 2, wherein the compounds have oxygen in the form of Al₂O₃.

6. A method according to claim 1, wherein the nuclei (9) have SiC, SiO, SiO₂, Si₃N₄, BN, BP, AlP, AlAs, AN or BeO.

7. A method according to claim 1, wherein the nuclei (9) have an effective nuclei density of 0.001 to 100 cm⁻².

8. A method according to claim 1, wherein the nuclei (9) have an effective nuclei density of 0.01 to 10 cm⁻².

9. A method according to claim 1, wherein the nuclei (9) have an effective nuclei density of 0.03 to 5 cm².

10. A method according to claim 1, wherein the nuclei (9) have a nucleus size of 0.01 to 50000 μm.

11. A method according to claim 1, wherein the nuclei (9) have a nucleus size of 0.1 to 5000 μm.

12. A method according to claim 1, wherein the nuclei (9) have a nucleus size of 1 to 500 μm.

13. A method according to claim 1, comprising an anchoring of the nuclei (9) in at least one of the base (2; 2a; 2b) and in at least one of the side walls (3; 3a; 3b).

14. A method according to claim 1, comprising an arrangement of the nuclei (9) directly on at least one of the base (2; 2a; 2b) and on at least one of the side walls (3; 3a; 3b).

15. A method according to claim 1, wherein the inner side (6) of at least one of the base (2; 2a; 2b) and at least one of the inner sides (7) of the side walls (3; 3a; 3b) has a coating (8; 8b).

16. A method according to claim 15, characterised by an anchoring of the nuclei (9) in the coating (8; 8b).

17. A method according to claim 15, comprising an arrangement of the nuclei (9) directly on the coating (8; 8b).

18. A method according to claim 15, comprising monocrystalline nuclei (9) with a preferred growth orientation (10) along a longitudinal axis (5) arranged perpendicular to the base (2; 2a; 2b).

19. A method according to claim 15, comprising an application of the nuclei (9), distributed statistically or in a structured manner, on the inner side (6) of at least one of the base (2; 2a; 2b) and the at least one inner side (7) of the side walls (3; 3a; 3b).

20. A method according to claim 19, wherein the nuclei (9) are present in dispersed form in a carrier medium, which evaporates before the silicon melts.

21. A method according to claim 20, wherein the carrier medium is a paste or a liquid, which is applied by spraying on, dropping on or punch pressure.

22. A crucible for producing silicon with
a. a base (2; 2a; 2b),
b. a plurality of side walls (3; 3a; 3b) and
c. nuclei (9) on at least an inner side (6) of the base (2; 2a; 2b) of the crucible (1; 1a; 1b; 1c),
d. wherein the base (2; 2a; 2b) and the side walls (3; 3a; 3b) partially surround an interior (4) to receive a silicon melt and
e. wherein the nuclei (9) have a melt temperature, which is greater than the melt temperature of silicon.
